(19) United States
(12) Patent Application Publication
(10) Pub. No.: US 2012/0050995 A1
(43) Pub. Date: Mar. 1, 2012

(54) HEAT DISSIPATION DEVICE AND CIRCUIT BOARD ASSEMBLY

(75) Inventor: ZHI-BIN GUAN, Tu-Cheng (TW)

(73) Assignee: HON HAI PRECISION INDUSTRY CO., LTD., Tu-Cheng (TW)

(21) Appl. No.: 12/881,141

(22) Filed: Sep. 13, 2010

(30) Foreign Application Priority Data
Aug. 31, 2010 (TW) 99129205

(51) Int. Cl. H05K 7/20

(52) U.S. Cl. 361/704

(57) ABSTRACT

A heat dissipation device includes a heat sink, and a mount mounted on a circuit board. The heat sink includes a base, a number of fins and a post extending from opposite sides of the base. The mount includes a number of arc-shaped fixing tabs extending from the circuit board. Threads are correspondingly formed on the post and the fixing tabs. The post is capable of pivotally and threadedly engaging with the fixing tabs to attach the heat sink to the circuit board.

### BACKGROUND

1. Technical Field

The present disclosure relates to a heat dissipation device and circuit board assembly.

2. Description of Related Art

In some computers or other electronic devices, heat dissipation devices cannot maintain close contact with elements after being subject to impacts or vibrations. As a result, heat generated by the elements cannot be dissipated as efficiently as desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a heat dissipation device, together with a circuit board.

FIG. 2 is an assembled, isometric view of the heat dissipation and the circuit board of FIG. 1.

FIG. 3 is across- sectional view of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

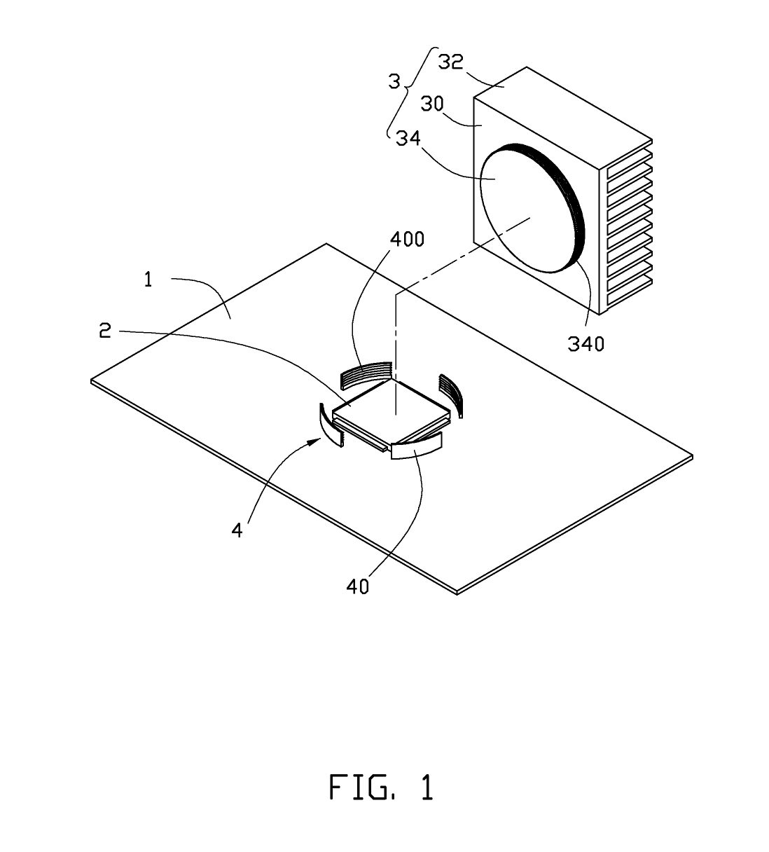

Referring to FIG. 1, in an exemplary embodiment, a heat dissipation device is used for dissipating heat for an electronic element 2 mounted on a circuit board 1. The heat dissipation device includes a heat sink 3 and a mount 4 mounted on the circuit board 1.

The heat sink 3 includes a base 30, a number of fins 32 extending from the top of the base 30, and a cylindrical post 34 extending down from the bottom of the base 30. Threads 340 are formed on a circumference of the post 34.

The mount 4 includes a number of spaced arc-shaped fixing tabs 40 which extend up from the circuit board 1 and surround the electronic element 2. Threads 400 are formed on surfaces of the fixing tabs 40 facing the electronic element 2.

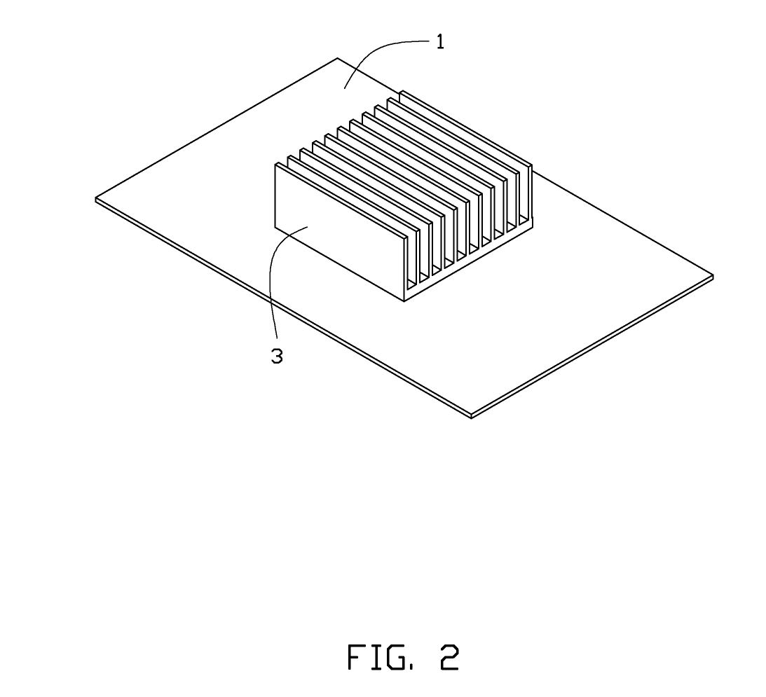

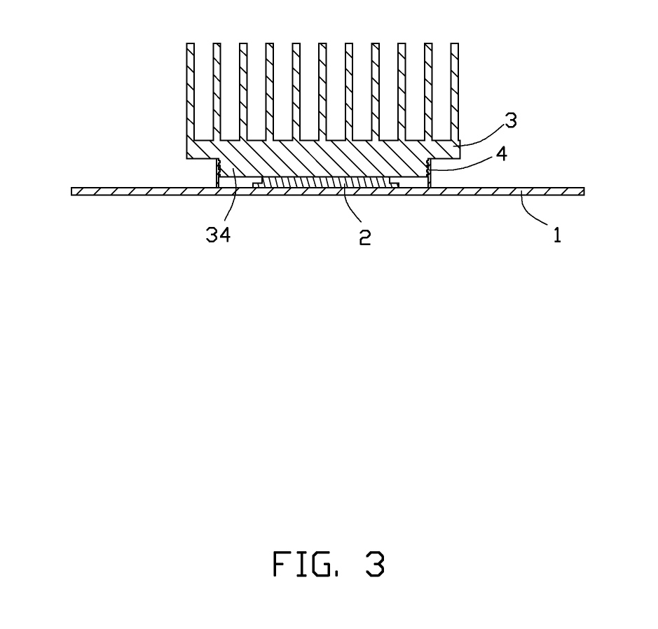

Referring to FIG. 2 and FIG. 3, in assembly, the post 34 is placed among the fixing tabs and rotated, thereby the threads 340 of the post 34 engage with the threads 400 of the fixing tabs 40. The bottom of the post 34 of the heat sink 3 contacts the electronic element 2. In this embodiment, a thermal pad is disposed between the post 34 of the heat sink 3 and the top of the electronic element 2; therefore heat dissipation can be maintained even after the shock of impact or vibrations occur.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A heat dissipation device, comprising:
a heat sink comprising a base, wherein a plurality of fins extend up from the base, a post extends down from the base, threads are formed on a circumference of the post; and
a mount mounted on a circuit board and surrounding a electronic element mounted on the circuit board; threads are formed on a surface of the mount facing the electronic element.
wherein the post is capable of pivotally and threadedly engaging with the mount to attach the heat sink to the element of the circuit board.

2. The heat dissipation device of claim 1, wherein the mount comprises a plurality of spaced arc-shaped fixing tabs, the threads of the mount are formed on surfaces of the fixing tabs facing the electronic element.

3. A circuit board assembly, comprising:
a circuit board comprising an electronic element mounted on the circuit board, and a mount extending from the circuit board and surrounding the electronic element, wherein threads are formed on the mount; and
a heat sink comprising a base, a plurality of fins extending from the base, and a post extending from the base opposite to the plurality of fins, wherein threads are formed on the post to engage with the threads of the mount; wherein a distal end of the post is attached on the electronic element.

4. The circuit board assembly of claim 3, wherein the mount comprises a plurality of spaced arc-shaped fixing tabs which extend from the circuit board and surround the electronic element.

5. The circuit board assembly of claim 4, wherein the post is coin-shaped, and the threads of the post are formed on a circumference of the post, and the threads of the mount are formed on surfaces of the plurality of fixing tabs facing the electronic element.
